(19) United States
(12) Patent Application Publication
(10) Pub. No.: US 2026/0198105 A1
(43) Pub. Date: Jul. 9, 2026

(54) SHORT-WAVE DUAL-BAND INFRARED DETECTOR BASED ON INDIUM PHOSPHIDE SUBSTRATE AND FABRICATION METHOD THEREOF

(71) Applicant: Institute of Semiconductors, Chinese Academy of Science, Beijing (CN)

(72) Inventors: Hongyue HAO, Beijing (CN); Yingqiang XU, Beijing (CN); Zhichuan NIU, Beijing (CN); Guowei WANG, Beijing (CN); Donghai WU, Beijing (CN); Dongwei JIANG, Beijing (CN); Xiangbin SU, Beijing (CN)

(73) Assignee: Institute of Semiconductors, Chinese Academy of Science, Beijing (CN)

(21) Appl. No.: 19/443,703

(22) Filed: Jan. 8, 2026

(30) Foreign Application Priority Data
Jan. 9, 2025 (CN) 202510037301X

(51) Int. Cl. H10F 30/24; H10F 71/00; H10F 77/124; H10F 77/14; H10F 77/20; H10F 77/30

(52) U.S. Cl. CPC H10F 30/24; H10F 71/1272; H10F 71/129; H10F 77/1248; H10F 77/146; H10F 77/241; H10F 77/306

(57) ABSTRACT

The present application relates to the field of infrared photoelectric materials and devices, and particularly to a short-wave dual-band infrared detector based on an indium phosphide substrate and a fabrication method thereof. An N-type doped indium phosphide substrate is used as a base of a device, and an indium phosphide absorption layer, a first P-type contact layer, a second P-type contact layer, a short-wave infrared superlattice absorption layer, and an N-type contact layer are sequentially grown on the N-type doped indium phosphide substrate. A lower metal electrode is in contact with the N-type doped indium phosphide substrate, and an upper metal electrode is in contact with the N-type contact layer and a light-transmitting hole is formed at a center of the upper metal electrode. In the present application, by using bandgap characteristics of the N-type doped indium phosphide substrate to participate in spectral absorption and converting the spectral absorption into an electrical signal for detection, a back-to-back diode structure is simultaneously employed to realize different responses to short-wave dual-band infrared by adjusting the bias voltage. Because the N-type doped indium phosphide substrate participates in spectral absorption, it is not necessary to remove the substrate in traditional methods, resulting in a simple epitaxial structure, reduced fabrication costs, and a simplified process.

### CROSS-REFERENCE TO RELATED APPLICATIONS

This application claims priority to Chinese Patent Application Number 202510037301X filed Jan. 9, 2025, which is incorporated herein by reference in its entirety.

### FIELD

The present application relates to the field of infrared photoelectric materials and devices, and particularly to a short-wave dual-band infrared detector based on an indium phosphide substrate and a fabrication method thereof.

### BACKGROUND OF THE INVENTION

Infrared detection is a passive detection technology and has extremely important applications in many fields. For single-band infrared detectors, contrast of images depends on a difference in radiation intensities between a target and a background. However, peaks of infrared radiation intensities of different radiation sources are in different band ranges. A short-wave dual-band infrared detector can be used to simultaneously acquire spectra of the target in different bands, enhancing the contrast between the target and the room-temperature background, and improving clarity of the images.

The short-wave dual-band infrared detector mainly includes a substrate and an epitaxial structure deposited on the substrate. In a structural design of the traditional short-wave dual-band infrared detector, the substrate serves only as the base for the epitaxial material to reduce defects introduced by epitaxially growth materials. The presence of the substrate reduces photoresponse, resulting in a single photoresponse band for the infrared detector. Therefore, it is necessary to provide a doped buffer layer at the substrate to reduce inter-channel crosstalk by increasing barrier height difference, and improve detection performance by decreasing dark current. Furthermore, after the infrared detector structure is prepared, the substrate is usually removed as much as possible to minimize its impact on light absorption efficiency, which inevitably leads to substrate waste and increased fabrication costs.

### BRIEF SUMMARY OF THE INVENTION

The present application provides a short-wave dual-band infrared detector based on an indium phosphide substrate and a fabrication method thereof to address defects that a traditional short-wave dual-band infrared detector has single light response band, reduced photoresponse due to substrate, and high fabrication costs.

The present application provides a short-wave dual-band infrared detector based on an indium phosphide substrate, including:
an N-type doped indium phosphide substrate; and
an epitaxial structure deposited on the N-type doped indium phosphide substrate,
where the epitaxial structure is etched into a cylindrical shape and forms a bench structure with the N-type doped indium phosphide substrate,
an annular lower metal electrode is provided at a location of the bench structure corresponding to the N-type doped indium phosphide substrate, and an annular upper metal electrode is provided at a location of the bench structure corresponding to a top of the epitaxial structure, a light-transmitting hole is formed at a center of the upper metal electrode, and a sulfide layer and a passivation layer are sequentially provided at a corresponding region of the bench structure other than the lower metal electrode, the upper metal electrode, and the light-transmitting hole.

The epitaxial structure includes: an indium phosphide absorption layer, a first P-type contact layer, a second P-type contact layer, a short-wave infrared superlattice absorption layer and an N-type contact layer. The indium phosphide absorption layer is grown on the indium phosphide substrate; the first P-type contact layer is grown on the indium phosphide absorption layer and doped with indium phosphide; the second P-type contact layer is grown on the first P-type contact layer and doped with aluminum gallium arsenide antimony alloy; the short-wave infrared superlattice absorption layer is grown on the second P-type contact layer; and the N-type contact layer is grown on the short-wave infrared superlattice absorption layer and doped with gallium arsenide indium.

According to the short-wave dual-band infrared detector based on the indium phosphide substrate provided by the present application, the N-type doped indium phosphide substrate is a (100)-oriented N-type sulfur-doped indium phosphide substrate.

According to the short-wave dual-band infrared detector based on the indium phosphide substrate provided by the present application, both the lower metal electrode and the upper metal electrode include, from bottom to top, a titanium layer, a platinum layer, and a gold layer, the titanium layer has a thickness of 20 nm to 80 nm, the platinum layer having a thickness of 20 nm to 80 nm, and the gold layer has a thickness of 250 nm to 400 nm; the titanium layer of the lower metal electrode is in contact with the N-type doped indium phosphide substrate, and the titanium layer of the upper metal electrode is in contact with the N-type contact layer.

According to the short-wave dual-band infrared detector based on the indium phosphide substrate provided by the present application, the indium phosphide absorption layer has a thickness of 500 nm to 2500 nm and a bandgap width of 1.34 eV to 1.35 eV.

According to the short-wave dual-band infrared detector based on the indium phosphide substrate provided by the present application, the short-wave infrared superlattice absorption layer is at least one of a gallium arsenide indium superlattice or a gallium arsenide antimony superlattice, and the short-wave infrared superlattice absorption layer has a thickness of 500 nm to 2500 nm, and a bandgap width of 1.34 eV to 1.35 eV.

According to the short-wave dual-band infrared detector based on the indium phosphide substrate provided by the present application, the short-wave infrared superlattice absorption layer includes a plurality of gallium arsenide indium superlattice layers and a plurality of gallium arsenide antimony superlattice layers, and the plurality of gallium arsenide indium superlattice layers and the plurality of gallium arsenide antimony superlattice layers are grown in an alternatively stacked manner to form the short-wave infrared superlattice absorption layer.

The present application further provides a method for fabricating a short-wave dual-band infrared detector based on an indium phosphide substrate, used in fabricating the short-wave dual-band infrared detector based on the indium phosphide substrate as described above, including:
using an N-type doped indium phosphide substrate as a structural substrate of the infrared detector, and performing degassing and deoxidation pretreatment on the N-type doped indium phosphide substrate;
homoepitaxially growing, based on pretreated N-type doped indium phosphide substrate, an indium phosphide absorption layer on the N-type doped indium phosphide substrate;
growing a first P-type contact layer on the indium phosphide absorption layer;
growing a second P-type contact layer on the first P-type contact layer;
growing a short-wave infrared superlattice absorption layer on the second P-type contact layer;
growing an N-type contact layer on the short-wave infrared superlattice absorption layer;
constituting an epitaxial structure deposited on the N-type doped indium phosphide substrate based on the indium phosphide absorption layer, the first P-type contact layer, the second P-type contact layer, the short-wave infrared superlattice absorption layer as well as the N-type contact layer, performing inductively coupled plasma (ICP) etching on sides of the epitaxial structure to make the epitaxial structure cylindrical;
covering the N-type doped indium phosphide substrate and the epitaxial structure with a sulfide layer and a passivation layer;
fabricating a mask by photolithography at a location of the passivation layer corresponding to the N-type doped indium phosphide substrate, forming a first annular opening through reactive ion etching, fabricating a mask by photolithography at a location of the passivation layer corresponding to the N-type contact layer, and forming a second annular opening through reactive ion etching, and
performing evaporative deposition treatment at the first annular opening to form an annular lower metal electrode, and performing evaporative deposition treatment at the second annular opening to form an annular upper metal electrode and a light-transmitting hole.

According to the method for fabricating the short-wave dual-band infrared detector based on the indium phosphide substrate provided by the present application, performing the degassing and deoxidation pretreatment on the N-type doped indium phosphide substrate includes:
placing the N-type doped indium phosphide substrate in a sample introduction chamber of a molecular beam epitaxy system, maintaining a temperature of the sample introduction chamber at 200° C., and performing low-temperature degassing for 150 min;
transferring the N-type doped indium phosphide substrate subjected to low-temperature degassing into a buffer chamber of the molecular beam epitaxy system, maintaining a temperature of the buffer chamber at 360° C., and performing high-temperature degassing for 60 min to 100 min; and
transferring the N-type doped indium phosphide substrate subjected to high-temperature degassing into a growth chamber of the molecular beam epitaxy system, gradually heating the N-type doped indium phosphide substrate to 500° C. to 700° C., and performing deoxidation treatment for 15 min to 30 min to remove oxides on a surface of the N-type doped indium phosphide substrate.

According to the method for fabricating the short-wave dual-band infrared detector based on the indium phosphide substrate provided by the present application, the indium phosphide absorption layer has a growth rate of 0.5 monolayer per second, and grown indium phosphide absorption layer has a thickness of 500 nm to 2500 nm;
the first P-type contact layer has a growth rate of 0.5 monolayer per second, and grown first P-type contact layer has a thickness of 200 nm to 400 nm;
the second P-type contact layer has a growth rate of 0.5 monolayer per second, and grown second P-type contact layer has a thickness of 400 nm to 600 nm;
the short-wave infrared superlattice absorption layer has a growth rate of 0.5 monolayer per second, and grown short-wave infrared superlattice absorption layer has a thickness of 500 nm to 2500 nm; and
the N-type contact layer has a growth rate of 0.5 monolayer per second, and grown N-type contact layer has a thickness of 7000 nm to 150 nm.

According to the method for fabricating the short-wave dual-band infrared detector based on the indium phosphide substrate provided by the present application, growing the short-wave infrared superlattice absorption layer on the second P-type contact layer includes:
growing a gallium arsenide indium superlattice layer on the second P-type contact layer, and growing a gallium arsenide antimony superlattice layer on grown gallium arsenide indium superlattice layer; and
using the grown gallium arsenide indium superlattice layer and grown gallium arsenide antimony superlattice layer as a periodic unit, continuing to grow a plurality of periodic units upwards until a total thickness of all periodic units reaches 500 nm to 2500 nm to form the short-wave infrared superlattice absorption layer.

In the short-wave dual-band infrared detector based on the indium phosphide substrate and the fabrication method thereof provided by the present application, an N-type doped indium phosphide substrate is used as a base of a device, and a (100)-oriented N-type sulfur (S)-doped indium phosphide (InP) substrate may be used. An indium phosphide absorption layer is directly grown on the N-type doped indium phosphide substrate; a first P-type contact layer is grown on the indium phosphide absorption layer and is doped with indium phosphide; a second P-type contact layer is grown on the first P-type contact layer and doped with aluminum gallium arsenide antimony alloy (AlGaAsSb); a short-wave infrared superlattice absorption layer is grown on the second P-type contact layer and is formed by alternatively stacking InGaAs and GaAsSb in multiple periods; and a N-type contact layer is grown on the short-wave infrared superlattice absorption layer and doped with gallium arsenide indium (InGaAs). Both the lower metal electrode and the upper metal electrode are annular, the lower metal electrode is provided at a location of a bench structure corresponding to the N-type doped indium phosphide substrate and in contact with the substrate, and the upper metal electrode is provided at a location of the bench structure corresponding to a top of the epitaxial structure and in contact with the N-type contact layer. A light-transmitting hole is formed at a center of the upper metal electrode for enabling light to enter an interior of the detector. A sulfide layer and a passivation layer are covered over a region other than the lower metal electrode, the upper metal electrode and the light-transmitting hole to protect the epitaxial structure and reduce undesirable surface states. In the present application, by using bandgap characteristics of the N-type doped indium phosphide substrate to participate in spectral absorption and converting the spectral absorption into an electrical signal for detection, a back-to-back diode structure is simultaneously employed to realize different responses to short-wave dual-band infrared by adjusting the bias voltage. Because the N-type doped indium phosphide substrate participates in spectral absorption, it is not necessary to remove the substrate in traditional methods, resulting in a simple epitaxial structure, reduced fabrication costs, and a simplified process.

### BRIEF DESCRIPTION OF THE DRAWINGS

To clearly illustrate solutions in the embodiments of the present application or in related art, the drawings used in the description of the embodiments or in related art are briefly described below. The drawings in the following description are only some embodiments of the present application, and other drawings may be obtained according to these drawings without any creative effort for those skilled in the art.

FIG. 1 is a cross-sectional schematic structural diagram of a short-wave dual-band infrared detector based on an indium phosphide substrate according to present application.

FIG. 2 is a schematic flowchart of a method for fabricating a short-wave dual-band infrared detector based on an indium phosphide substrate according to present application.

FIG. 3 is a spectral response diagram of a short-wave dual-band infrared detector based on an indium phosphide substrate according to present application.

### REFERENCE SIGNS

1: N-type doped indium phosphide substrate; 2: lower metal electrode; 3: upper metal electrode; 4: light-transmitting hole; 5: passivation layer; 6: indium phosphide absorption layer; 7: first P-type contact layer; 8: second P-type contact layer; 9: short-wave infrared superlattice absorption layer; 10: N-type contact layer.

### DETAILED DESCRIPTION OF THE INVENTION

In order to make objectives, solutions, and advantages of the present application clearer, the solutions of the present application will be described blow clearly and completely in conjunction with the accompanying drawings in the present application. It is apparent that the described embodiments are only a part of the embodiments of the present application, rather than all of them. Based on the embodiments of the present application, all other embodiments obtained by those of ordinary skill in the art without making creative efforts shall fall within the scope of protection of the present application.

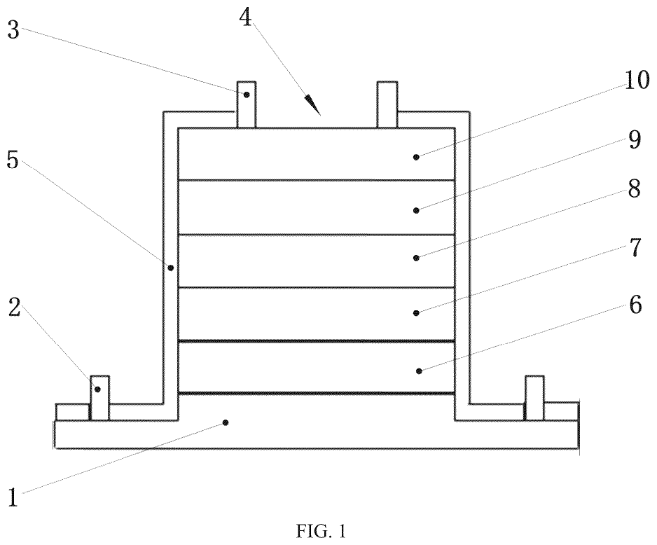

A short-wave dual-band infrared detector based on an indium phosphide substrate and a fabrication method thereof are described below with reference to FIG. 1 to FIG. 3.

An embodiment of the present application provides a short-wave dual-band infrared detector based on an indium phosphide substrate. Referring to FIG. 1, the short-wave dual-band infrared detector includes an N-type doped indium phosphide substrate 1 and an epitaxial structure deposited on the N-type doped indium phosphide substrate 1. The epitaxial structure is etched into a cylindrical shape and forms a bench structure with the N-type doped indium phosphide substrate 1. An annular lower metal electrode 2 is provided at a location of the bench structure corresponding to the N-type doped indium phosphide substrate 1, and an annular upper metal electrode 3 is provided at a location of the bench structure corresponding to a top of the epitaxial structure, a light-transmitting hole 4 is formed at a center of the upper metal electrode 3, and a sulfide layer and a passivation layer 5 are sequentially provided at a corresponding region of the bench structure other than the lower metal electrode 2, the upper metal electrode 3, and the light-transmitting hole 4.

The epitaxial structure includes: an indium phosphide absorption layer 6, a first P-type contact layer 7, a second P-type contact layer 8, a short-wave infrared superlattice absorption layer 9 and an N-type contact layer 10. The indium phosphide absorption layer 6 is grown on the indium phosphide substrate 1; the first P-type contact layer 7 is grown on the indium phosphide absorption layer 6 and doped with indium phosphide; the second P-type contact layer 8 is grown on the first P-type contact layer 7 and doped with aluminum gallium arsenide antimony alloy; the short-wave infrared superlattice absorption layer 9 is grown on the second P-type contact layer; and the N-type contact layer 10 is grown on the short-wave infrared superlattice absorption layer 9 and doped with gallium arsenide indium.

It is understood that in the short-wave dual-band infrared detector structure based on an indium phosphide substrate, the N-type doped indium phosphide substrate 1 serves as a base of a device, and a (100)-oriented N-type sulfur (S)-doped indium phosphide (InP) substrate may be used. The indium phosphide absorption layer 6 is directly grown on the N-type doped indium phosphide substrate 1; the first P-type contact layer 7 is grown on the indium phosphide absorption layer 6 and is doped with indium phosphide; the second P-type contact layer 8 is grown on the first P-type contact layer 7 and doped with aluminum gallium arsenide antimony alloy (AlGaAsSb); the short-wave infrared superlattice absorption layer 9 is grown on the second P-type contact layer 8 and is formed by alternatively stacking InGaAs and GaAsSb in multiple periods; and the N-type contact layer 10 is grown on the short-wave infrared superlattice absorption layer 9 and doped with gallium arsenide indium (InGaAs). Both the lower metal electrode 2 and the upper metal electrode 3 are annular, the lower metal electrode 2 is provided at a location of a bench structure corresponding to the N-type doped indium phosphide substrate 1 and in contact with the substrate, and the upper metal electrode 3 is provided at a location of the bench structure corresponding to a top of the epitaxial structure and in contact with the N-type contact layer 10, and a light-transmitting hole 4 is formed at a center of the upper metal electrode for enabling light to enter an interior of the detector. A sulfide layer and a SiO₂ passivation layer 5 are covered over a region other than the lower metal electrode 2, the upper metal electrode 3 and the light-transmitting hole 4 to protect the epitaxial structure and reduce undesirable surface states.

In the embodiment of the present application, by using bandgap characteristics of the N-type doped indium phosphide substrate 1 to participate in spectral absorption and converting the spectral absorption into an electrical signal for detection, a back-to-back diode structure is simultaneously employed to realize different responses to short-wave dual-band infrared by adjusting the bias voltage. Because the N-type doped indium phosphide substrate 1 participates in spectral absorption, it is not necessary to remove the substrate in traditional methods as long as the substrate only needs to be thinned to between 100 nm and 500 nm. In this embodiment, the substrate is used as a device structure, reducing fabrication costs, and simplifying the process.

In some embodiments of the short-wave dual-band infrared detector based on the indium phosphide substrate according to the present application, the N-type doped indium phosphide substrate 1 is a (100)-oriented N-type sulfur-doped indium phosphide substrate. (100) orientation is a commonly used crystal orientation in semiconductor materials, providing good crystal quality and helping to reduce defect density during epitaxial growth, thereby improving device performance. Sulfur (S), as an N-type dopant, may adjust a conductivity type and concentration of indium phosphide substrates, optimize concentration of a carrier, improve electrical properties, and facilitate growth of subsequent epitaxial layers. Appropriate concentrations of S doping can also enhance light absorption efficiency of indium phosphide substrates, especially in the infrared band. In the present application, the N-type doped indium phosphide substrate 1 forms a PN junction with subsequently grown P-type layer, which is crucial for manufacturing diode structures.

Unlike traditional infrared detectors in which the substrate needs to be removed to reduce the impact of the substrate on light absorption efficiency, the N-type doped indium phosphide substrate 1 in the present application not only serves as the basis for epitaxial growth but also directly participates in spectral absorption using its bandgap characteristics, and the spectral absorption is converted into an electrical signal for detection. Since the substrate itself becomes part of the detector, it is not necessary to completely remove the substrate during thinning, which simplifies the structure of the device and reduces production costs. By using a (100)-oriented N-type sulfur-doped indium phosphide substrate, the N-type doped indium phosphide (InP) substrate 1 can increase the absorption of light having a specific wavelength without affecting the main functions of the detector, thereby improving the overall light response efficiency and detection sensitivity. (100)-oriented N-type sulfur-doped InP is used for fabricating the substrate to optimize overall performance of the detector, including but not limited to improving light absorption efficiency, simplifying the fabrication process, and reducing costs and plays a crucial role in fabricating a high-efficiency short-wave dual-band infrared detector.

In some embodiments of the short-wave dual-band infrared detector based on an indium phosphide substrate according to the present application, both the lower metal electrode 2 and the upper metal electrode 3 include, from bottom to top, a titanium layer, a platinum layer, and a gold layer, the titanium layer has a thickness of 20 nm to 80 nm, the platinum layer having a thickness of 20 nm to 80 nm, and the gold layer has a thickness of 250 nm to 400 nm; the titanium layer of the lower metal electrode 2 is in contact with the N-type doped indium phosphide substrate 1, and the titanium layer of the upper metal electrode 3 is in contact with the N-type contact layer 10.

It is understandable that in some specific examples, the titanium layer has a thickness of 50 nm. The titanium layer, as a bottom layer of the electrode, provides good adhesion, ensures a stable contact between the metal electrode and the semiconductor material, and may form a low-resistance ohmic contact. The platinum layer having a thickness of 50 nm and being provided at the titanium layer enhances the thermal and chemical stability of the entire metal layer and prevents the titanium layer from diffusing into the InP or N-type contact layer during high-temperature processing, ensuring long-term electrode reliability. The gold layer having a thickness of 300 nm and serving as the top layer provides excellent conductivity and protects the internal titanium and platinum layers from environmental factors due to its superior corrosion resistance.

The titanium layer of the lower metal electrode 2 directly is in contact with the N-type doped indium phosphide substrate 1 to ensure a good electrical connection from the substrate to the electrode, facilitating the efficient collection and transport of photogenerated carriers while maintaining low contact resistance. The titanium layer of the upper metal electrode 3 is in contact with the N-type contact layer 10 in the epitaxial structure, performing a similar current collection function. The light-transmitting hole is formed at a center of the annular upper metal electrode to allow light to smoothly enter an effective area of the detector for efficiently performing light absorption and conversion.

In the present embodiment, by selecting appropriate material combinations and thickness ratios of the metal electrode, optimal ohmic contact of the electrodes is achieved, contact resistance is reduced and the overall efficiency of the device is improved. Excellent adhesion of the titanium layer and high melting point of the platinum layer jointly enhance the mechanical strength and durability of the electrode under various processing conditions. The platinum layer is provided to effectively prevent titanium from diffusing into the semiconductor material, especially at high temperatures, which is crucial for maintaining long-term stable electrical performance. The structure of the metal electrode in the present embodiment plays a key role in ensuring the high efficiency, high stability, and long lifespan of short-wave dual-band infrared detector based on the indium phosphide substrate.

In some embodiments of the short-wave dual-band infrared detector based on an indium phosphide substrate according to the present application, the indium phosphide absorption layer 6 has a thickness of 500 nm to 2500 nm and a bandgap width of 1.34 eV to 1.35 eV. The short-wave infrared superlattice absorption layer 9 is at least one of a gallium arsenide indium superlattice or a gallium arsenide antimony superlattice, and the short-wave infrared superlattice absorption layer 9 has a thickness of 500 nm to 2500 nm, and a bandgap width of 1.34 eV to 1.35 eV.

It is understood that the indium phosphide absorption layer 6 is grown directly on the N-type doped indium phosphide substrate 1. As the first light-absorbing layer of the detector, the bandgap width of the indium phosphide absorption layer 6 determines its capability to effectively absorb photons within a specific wavelength range and convert them into electron-hole pairs. Indium phosphide exhibits good absorption efficiency for short-wave infrared light within this bandgap range, making it particularly suitable for short-wave dual-band infrared detection applications. The short-wave infrared superlattice absorption layer 9, located above the second P-type contact layer 8, is a crucial part of the detector responsible for absorbing infrared light in another band. By selecting an appropriate InGaAs or GaAsSb superlattice structure, its bandgap width can be precisely controlled to match with a target detection wavelength. This superlattice structure may provide additional quantum confinement effects, thereby enhancing the absorption efficiency for light with a specific wavelength while maintaining a low dark current level and improving a signal-to-noise ratio.

In some embodiments of the short-wave dual-band infrared detector based on an indium phosphide substrate according to the present application, the short-wave infrared superlattice absorption layer 9 includes a plurality of gallium arsenide indium superlattice layers and a plurality of gallium arsenide antimony superlattice layers, and the plurality of gallium arsenide indium superlattice layers and the plurality of gallium arsenide antimony superlattice layers are grown in an alternatively stacked manner to form the short-wave infrared superlattice absorption layer 9.

It is understood that in the present embodiment, an InGaAs superlattice layer and a GaAsSb superlattice layer are grown alternatively to form a multi-layered alternatively stacked structure. The superlattice layer made of each material has a specific thickness and periodicity to obtain the desired bandgap. InGaAs and GaAsSb possess complementary optical and electrical properties. InGaAs has better absorption efficiency for infrared light with a shorter wavelength, while GaAsSb can effectively absorb infrared light with a longer wavelength. The combination of InGaAs and GaAsSb can extend the absorption spectral range, covering a wider short-wave infrared region. The thickness and stacking period of each superlattice layer are precisely designed to ensure that the bandgap width of the entire short-wave infrared superlattice absorption layer 9 remains between 1.34 eV and 1.35 eV, thereby optimizing the absorption efficiency for infrared light in the target wavelength band.

In the present embodiment, by alternatively stacking InGaAs and GaAsSb materials with different bandgap widths, two different short-wave infrared light can be efficiently detected within a single device, which not only increases application flexibility of the detector but also improves imaging quality and target recognition capabilities. A quantum confinement effect, where electrons and holes are confined in one or more quantum wells, is introduced in the superlattice structure, which may enhance the absorption of photons at specific wavelengths while reducing the number of thermally generated charge carriers, lowering dark current, and improving the signal-to-noise ratio. Due to the quantum confinement effect, the detector can operate at lower temperatures and has a lower dark current level, which is particularly important for weak signal detection. The superlattice structure of the present embodiment makes the detector more sensitive to photons in the target wavelength band while maintaining high spatial resolution, making it suitable for a variety of high-precision infrared imaging and sensing applications. Since InGaAs and GaAsSb are highly compatible with the traditional semiconductor manufacturing processes, these complex superlattice structures can be fabricated through traditional epitaxial growth techniques such as metal-organic chemical vapor deposition (MOCVD) or molecular beam epitaxy (MBE), ensuring the feasibility of large-scale production.

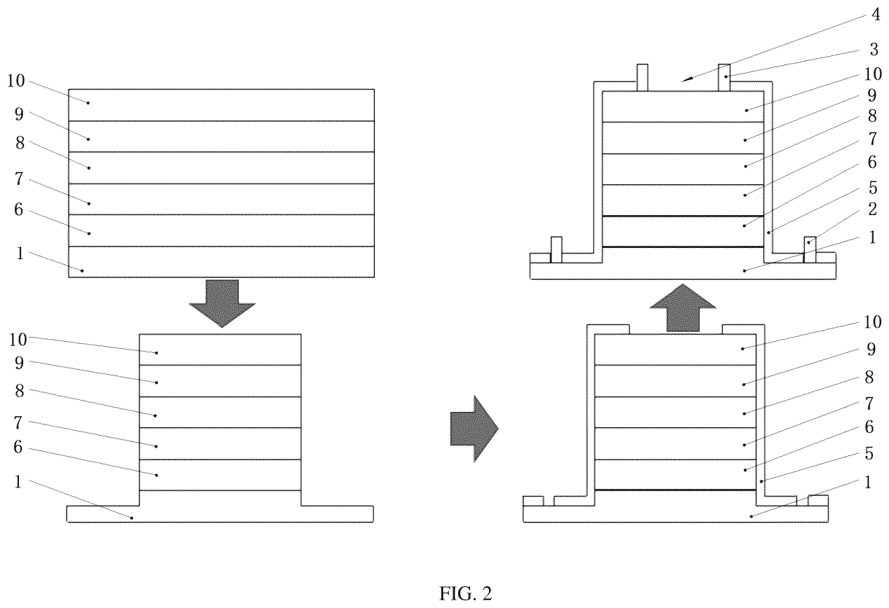

The present application further provides a method for fabricating a short-wave dual-band infrared detector based on an indium phosphide substrate, used in fabricating the short-wave dual-band infrared detector based on the indium phosphide substrate as described above. In some specific embodiments of the method for fabricating the short-wave dual-band infrared detector based on the indium phosphide substrate, as shown in FIG. 2, the fabrication method includes the following steps S1 to S10.

In S1, an N-type doped indium phosphide substrate 1 is used as a structural substrate of the infrared detector, and degassing and deoxidation pretreatment is performed on the N-type doped indium phosphide substrate 1.

S1 is performed to ensure that a surface of the N-type doped indium phosphide substrate 1 is clean by removing oxides and other contaminants. Specifically, the N-type doped indium phosphide substrate 1 is placed firstly in a sample introduction chamber of a molecular beam epitaxy system, a temperature of the sample introduction chamber is maintained at 200° C., and low-temperature degassing is performed for 150 min; the N-type doped indium phosphide substrate 1 subjected to low-temperature degassing is then transferred into a buffer chamber of the molecular beam epitaxy system, a temperature of the buffer chamber is maintained at 360° C., and high-temperature degassing is performed for 60 min to 100 min; and the N-type doped indium phosphide substrate 1 subjected to high-temperature degassing is finally transferred into a growth chamber of the molecular beam epitaxy system, the N-type doped indium phosphide substrate is gradually heated to 500° C. to 700° C., and deoxidation treatment is performed for 15 min to 30 min to remove oxides on a surface of the N-type doped indium phosphide substrate 1.

In S2, an indium phosphide absorption layer 6 is homoepitaxially grown, based on pretreated N-type doped indium phosphide substrate 1, on the N-type doped indium phosphide substrate 1.

S2 is performed to provide a high-quality base layer before epitaxial growth. Specifically, an indium phosphide absorption layer 6 having a thickness of 1500 nm is homoepitaxially grown at a growth rate of 0.5 monolayer per second on the N-type doped indium phosphide substrate 1 subjected to deoxidation treatment in step S1.

In S3, a first P-type contact layer 7 is grown on the indium phosphide absorption layer 6.

S3 is performed to form good electrical contacts and provide a support for subsequent layers. Specifically, the first P-type contact layer 7 having a thickness of 300 nm is grown on the indium phosphide absorber layer 6 grown in step S2, and the first P-type contact layer 7 is doped with In and has a growth rate of 0.5 monolayer per second.

In S4, a second P-type contact layer 8 is grown on the first P-type contact layer 7.

S4 is performed to further optimize electrical performance for the growth of a short-wave infrared superlattice absorber layer 9. Specifically, the second P-type contact layer 8 having a thickness of 500 nm is grown on the first P-type contact layer 7 grown in step S3, and the second P-type contact layer 8 is doped with AlGaAsSb.

In S5, a short-wave infrared superlattice absorption layer 9 is grown on the second P-type contact layer 8.

S5 is performed to construct an absorption region sensitive to light with a specific wavelength. Specifically, a short-wave infrared superlattice absorption layer 9 having a thickness of 2000 nm is then grown on the second P-type contact layer 8 grown in step S4. The short-wave infrared superlattice absorption layer 9 is a stacked structure of InGaAs having a thickness of d1 and GaAsSb having a thickness of d2. By repeatedly growing for n periods, with d1+d2 as a period, a short-wave infrared superlattice with precisely controlled composition can be obtained.

In S6, an N-type contact layer 10 is grown on the short-wave infrared superlattice absorption layer 9.

S6 is performed to provide a final electron collection layer and form good contact with the metal upper electrode. Specifically, a N-type contact layer 10 having a thickness of 100 nm is grown on the short-wave infrared superlattice absorption layer 9 in step S5 and the N-type contact layer 10 is doped with InGaAs.

In S7, an epitaxial structure deposited on the N-type doped indium phosphide substrate 1 is constituted from the indium phosphide absorption layer 6, the first P-type contact layer 7, the second P-type contact layer 8, the short-wave infrared superlattice absorption layer 9 as well as the N-type contact layer 10, and inductively coupled plasma (ICP) etching is performed on sides of the epitaxial structure to make the epitaxial structure cylindrical.

S7 is performed to process the epitaxial structure to have a desired cylindrical shape through etching. Specifically, ICP etching is performed on sides of the epitaxial structure deposited on the N-type doped indium phosphide substrate obtained in S6 to form a bench and the remaining epitaxial structure is cylindrical. Gas used in ICP etching is CH4:Cl2:Ar, CH4:Cl2:BCl3:Ar, or Cl2:BCl3: Ar with appropriate ratios. The bench has a depth of 4700 nm and extended to the N-type doped indium phosphide substrate 1.

In S8, the N-type doped indium phosphide substrate 1 and the epitaxial structure is covered with a sulfide layer and a passivation layer 5.

S8 is performed to protect the epitaxial structure and reduce the influence of surface states. Specifically, a device etched in step S7 is covered with a sulfide layer and SiO2 passivation layer 5 having a thickness of 300 nm prepared using plasma chemical vapor deposition (PCVD).

S9: a mask is fabricated by photolithography at a location of the passivation layer 5 corresponding to the N-type doped indium phosphide substrate 1, a first annular opening is formed through reactive ion etching, a mask is fabricated by photolithography at a location of the passivation layer 5 corresponding to the N-type contact layer 10, and a second annular opening is formed through reactive ion etching.

S9 is performed to prepare for subsequent electrode evaporation. Specifically, the SiO2 passivation layer 5 fabricated in step S8 is subjected to opening treatment. A mask is fabricated by photolithography, and the opening is etched through reactive ion etching (RIE). The treatment area includes the predetermined area of the lower metal electrode 2, the upper metal electrode 3, and the light-transmitting hole 4.

In S10, evaporative deposition treatment is performed at the first annular opening to form an annular lower metal electrode 2 and evaporative deposition treatment is performed at the second annular opening to form an annular upper metal electrode 3 and a light-transmitting hole 4.

S10 is performed to form metal electrodes for electrical connection. Specifically, evaporative deposition treatment is performed on the upper metal electrode and lower metal electrode regions, respectively, located at the upper surface and lower surface of the bench as preset in step S9. Ti/Pt/Au layers having thicknesses of 50 nm/50 nm/300 nm, respectively of the lower metal electrode 2 and upper metal electrode 3 are evaporated through electron beams. The upper metal electrode 3 is annular and formed at the upper surface of the bench and the Ti layer is in contact with the short-wave infrared N-type contact layer 10. The lower metal electrode 2 is annular and formed at the upper surface of the bench and the Ti layer is in contact with the S-doped N-type indium phosphide substrate 1.

It is noted that the thickness values mentioned in the present application are only examples and are not limited thereto.

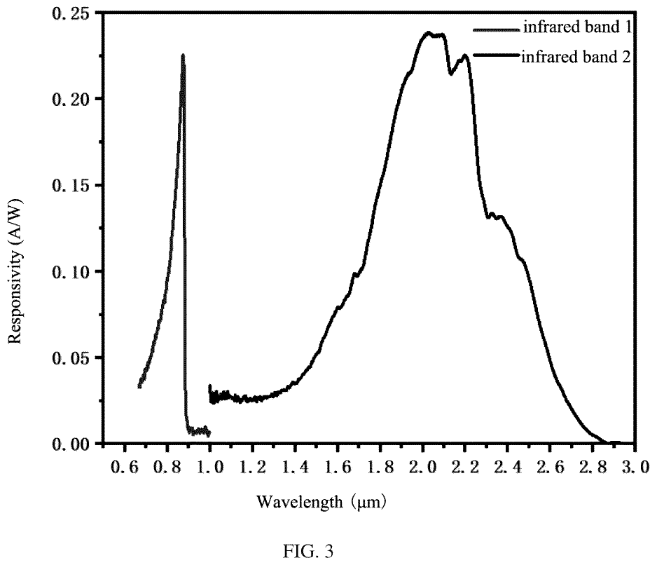

In summary, in the method for fabricating a short-wave dual-band infrared detector based on an indium phosphide substrate according to the present embodiment, through a series of precisely controlled process steps, from substrate pretreatment to formation of final electrode, the short-wave dual-band infrared detector based on indium phosphide substrate is ensured to have the characteristics of high efficiency, high stability and long lifespan. Each step is carefully designed to achieve the optimal material quality and device performance, thereby meeting the requirements of high-performance infrared detection. For the short-wave dual-band infrared detector based on the indium phosphide substrate fabricated using the method for fabricating the short-wave dual-band infrared detector based on the indium phosphide substrate, by using bandgap characteristics of the N-type doped indium phosphide substrate 1 to participate in spectral absorption and converting the spectral absorption into an electrical signal for detection, a back-to-back diode structure is simultaneously employed to realize different responses to short-wave dual-band infrared by adjusting the bias voltage. Referring to FIG. 3 showing a spectral response diagram of a short-wave dual-band infrared detector based on an indium phosphide substrate, the short-wave dual-band infrared detector based on the indium phosphide substrate may respond to the first infrared short-wave band with wavelengths of 0.7 μm to 0.9 μm, and also to the second infrared short-wave band with wavelengths of 1.4 μm to 2.8 μm. Because the N-type doped indium phosphide substrate 1 participates in spectral absorption, it is not necessary to remove the substrate in traditional methods, resulting in a simple epitaxial structure, reduced fabrication costs, and a simplified process.

Finally, it should be noted that the above embodiments are only used to illustrate the solutions of the present application, and not to limit them. Although the present application has been described in detail with reference to the foregoing embodiments, those skilled in the art should understand that modifications can still be made to the solutions described in the foregoing embodiments, or equivalent substitutions can be made to some of the features; and these modifications or substitutions do not cause the essence of the corresponding solutions to deviate from the scope of the technical solutions of the embodiments of the present application.

We claim:

1. A short-wave dual-band infrared detector based on an indium phosphide substrate, comprising:
an N-type doped indium phosphide substrate; and
an epitaxial structure deposited on the N-type doped indium phosphide substrate,
wherein the epitaxial structure is etched into a cylindrical shape and forms a bench structure with the N-type doped indium phosphide substrate,
wherein an annular lower metal electrode is provided at a location of the bench structure corresponding to the N-type doped indium phosphide substrate, and an annular upper metal electrode is provided at a location of the bench structure corresponding to a top of the epitaxial structure, a light-transmitting hole is formed at a center of the upper metal electrode, and a sulfide layer and a passivation layer are sequentially provided at a corresponding region of the bench structure other than the lower metal electrode, the upper metal electrode, and the light-transmitting hole;
wherein the epitaxial structure comprises:
an indium phosphide absorption layer grown on the indium phosphide substrate;
a first P-type contact layer grown on the indium phosphide absorption layer, the first P-type contact layer being doped with indium phosphide;
a second P-type contact layer grown on the first P-type contact layer, the second P-type contact layer being doped with aluminum gallium arsenide antimony alloy;
a short-wave infrared superlattice absorption layer grown on the second P-type contact layer; and
an N-type contact layer grown on the short-wave infrared superlattice absorption layer, the N-type contact layer being doped with gallium arsenide indium.

2. The short-wave dual-band infrared detector based on the indium phosphide substrate of claim 1, wherein the N-type doped indium phosphide substrate is a (100)-oriented N-type sulfur-doped indium phosphide substrate.

3. The short-wave dual-band infrared detector based on the indium phosphide substrate of claim 1, wherein both the lower metal electrode and the upper metal electrode comprise, from bottom to top, a titanium layer, a platinum layer, and a gold layer, the titanium layer having a thickness of 20 nm to 80 nm, the platinum layer having a thickness of 20 nm to 80 nm, and the gold layer having a thickness of 250 nm to 400 nm; the titanium layer of the lower metal electrode is in contact with the N-type doped indium phosphide substrate, and the titanium layer of the upper metal electrode is in contact with the N-type contact layer.

4. The short-wave dual-band infrared detector based on the indium phosphide substrate of claim 1, wherein the indium phosphide absorption layer has a thickness of 500 nm to 2500 nm and a bandgap width of 1.34 eV to 1.35 eV.

5. The short-wave dual-band infrared detector based on the indium phosphide substrate of claim 1, wherein the short-wave infrared superlattice absorption layer is at least one of a gallium arsenide indium superlattice or a gallium arsenide antimony superlattice, and the short-wave infrared superlattice absorption layer has a thickness of 500 nm to 2500 nm, and a bandgap width of 1.34 eV to 1.35 eV.

6. The short-wave dual-band infrared detector based on the indium phosphide substrate of claim 5, wherein the short-wave infrared superlattice absorption layer comprises a plurality of gallium arsenide indium superlattice layers and a plurality of gallium arsenide antimony superlattice layers, the plurality of gallium arsenide indium superlattice layers and the plurality of gallium arsenide antimony superlattice layers being grown in an alternatively stacked manner to form the short-wave infrared superlattice absorption layer.

7. A method for fabricating a short-wave dual-band infrared detector based on an indium phosphide substrate, used in fabricating the short-wave dual-band infrared detector based on the indium phosphide substrate in claim 1, comprising:
using an N-type doped indium phosphide substrate as a structural substrate of the infrared detector, and performing degassing and deoxidation pretreatment on the N-type doped indium phosphide substrate;
homoepitaxially growing, based on pretreated N-type doped indium phosphide substrate, an indium phosphide absorption layer on the N-type doped indium phosphide substrate;
growing a first P-type contact layer on the indium phosphide absorption layer;
growing a second P-type contact layer on the first P-type contact layer;
growing a short-wave infrared superlattice absorption layer on the second P-type contact layer;
growing an N-type contact layer on the short-wave infrared superlattice absorption layer;
constituting an epitaxial structure deposited on the N-type doped indium phosphide substrate based on the indium phosphide absorption layer, the first P-type contact layer, the second P-type contact layer, the short-wave infrared superlattice absorption layer as well as the N-type contact layer, performing inductively coupled plasma (ICP) etching on sides of the epitaxial structure to make the epitaxial structure cylindrical;
covering the N-type doped indium phosphide substrate and the epitaxial structure with a sulfide layer and a passivation layer;
fabricating a mask by photolithography at a location of the passivation layer corresponding to the N-type doped indium phosphide substrate, forming a first annular opening through reactive ion etching, fabricating a mask by photolithography at a location of the passivation layer corresponding to the N-type contact layer, and forming a second annular opening through reactive ion etching, and
performing evaporative deposition treatment at the first annular opening to form an annular lower metal electrode, and performing evaporative deposition treatment at the second annular opening to form an annular upper metal electrode and a light-transmitting hole.

8. The method for fabricating the short-wave dual-band infrared detector based on the indium phosphide substrate of claim 7, wherein performing the degassing and deoxidation pretreatment on the N-type doped indium phosphide substrate comprises:
placing the N-type doped indium phosphide substrate in a sample introduction chamber of a molecular beam epitaxy system, maintaining a temperature of the sample introduction chamber at 200° C., and performing low-temperature degassing for 150 min;
transferring the N-type doped indium phosphide substrate subjected to low-temperature degassing into a buffer chamber of the molecular beam epitaxy system, maintaining a temperature of the buffer chamber at 360° C., and performing high-temperature degassing for 60 min to 100 min; and
transferring the N-type doped indium phosphide substrate subjected to high-temperature degassing into a growth chamber of the molecular beam epitaxy system, gradually heating the N-type doped indium phosphide substrate to 500° C. to 700° C., and performing deoxidation treatment for 15 min to 30 min to remove oxides on a surface of the N-type doped indium phosphide substrate.

9. The method for fabricating the short-wave dual-band infrared detector based on the indium phosphide substrate of claim 7, wherein
the indium phosphide absorption layer has a growth rate of 0.5 monolayer per second, and grown indium phosphide absorption layer has a thickness of 500 nm to 2500 nm;
the first P-type contact layer has a growth rate of 0.5 monolayer per second, and grown first P-type contact layer has a thickness of 200 nm to 400 nm;
the second P-type contact layer has a growth rate of 0.5 monolayer per second, and grown second P-type contact layer has a thickness of 400 nm to 600 nm;
the short-wave infrared superlattice absorption layer has a growth rate of 0.5 monolayer per second, and grown short-wave infrared superlattice absorption layer has a thickness of 500 nm to 2500 nm; and
the N-type contact layer has a growth rate of 0.5 monolayer per second, and grown N-type contact layer has a thickness of 150 nm to 2500 nm.

10. The method for fabricating the short-wave dual-band infrared detector based on the indium phosphide substrate of claim 7, wherein growing the short-wave infrared superlattice absorption layer on the second P-type contact layer comprises:
growing a gallium arsenide indium superlattice layer on the second P-type contact layer, and growing a gallium arsenide antimony superlattice layer on grown gallium arsenide indium superlattice layer; and
using the grown gallium arsenide indium superlattice layer and grown gallium arsenide antimony superlattice layer as a periodic unit, continuing to grow a plurality of periodic units upwards until a total thickness of all periodic units reaches 500 nm to 2500 nm to form the short-wave infrared superlattice absorption layer.
